(19) United States
(12) Patent Application Publication
(10) Pub. No.: US 2016/0155881 A1
(43) Pub. Date: Jun. 2, 2016

(54) THIN FILM III-V OPTOELECTRONIC DEVICE OPTIMIZED FOR NON-SOLAR ILLUMINATION SOURCES

(71) Applicant: Alta Devices, Inc., Sunnyvale, CA (US)

(72) Inventors: Brendan M. KAYES, Los Gatos, CA (US); Gregg S. HIGASHI, San Jose, CA (US); Sam COWLEY, Mountain View, CA (US); Christopher FRANCE, Campbell, CA (US); Ling ZHANG, San Jose, CA (US); Gang HE, Cupertino, CA (US)

(21) Appl. No.: 15/006,003

(22) Filed: Jan. 25, 2016

Related U.S. Application Data
(63) Continuation-in-part of application No. 13/705,064, filed on Dec. 4, 2012.
Application No. 13/705,064 is a continuation-in-part of application No. 12/939,077, filed on Nov. 3, 2010, now abandoned.
Application No. 12/939,077 is a continuation-in-part of application No. 12/605,108, filed on Oct. 23, 2009, now Pat. No. 8,937,244.
Application No. 12/605,108 is a continuation-in-part of application No. 14/846,675, filed on Sep. 4, 2015.
Application No. 14/846,675 is a continuation-in-part of application No. 12/904,047, filed on Oct. 13, 2010.
Application No. 12/904,047 is a continuation-in-part of application No. 13/446,876, filed on Apr. 13, 2012.
Application No. 13/446,876 is a continuation-in-part of application No. 13/354,175, filed on Jan. 19, 2012, now Pat. No. 9,136,422.
Application No. 13/354,175 is a continuation-in-part of application No. 14/452,393, filed on Aug. 5, 2014.
(60) Provisional application No. 62/108,387, filed on Jan. 27, 2015.

(51) Int. Cl. H01L 31/109; H01L 31/18; H01L 31/0232

(52) U.S. Cl. CPC H01L 31/109; H01L 31/0232; H01L 31/18

(57) ABSTRACT

An optoelectronic device with high band-gap absorbers optimized for indoor use and a method of manufacturing are disclosed. The optoelectronic semiconductor device comprises a p-n structure made of one or more compound semiconductors, wherein the p-n structure comprises a base layer and an emitter layer, wherein the base and/or emitter layers comprise materials whose quantum efficiency spectrum is well-matched to a spectrum of incident light, wherein the incident light is from a light source other than the sun; and wherein the device is a flexible single-crystal device. The method for forming an optoelectronic device optimized for the conversion of light from non-solar illumination sources into electricity, comprises depositing a buffer layer on a wafer; depositing a release layer above the buffer layer; depositing a p-n structure above the release layer; and lifting off the p-n structure from the wafer.

### CROSS-REFERENCE TO RELATED APPLICATION

The present application claims the benefit of U.S. Provisional Application No. 62/108,387 (Docket No. 0067PR/5222PR), filed on Jan. 27, 2015, entitled “THIN FILM InGaP OPTOELECTRONIC DEVICE,” which is incorporated herein by reference in its entirety. Under 35 U.S.C. 120, this application is a Continuation-in-Part and claims priority to U.S. application Ser. No. 13/705,064 (Docket No. 0061P/5123P), filed on Dec. 4, 2012, entitled “MULTI-JUNCTION OPTOELECTRONIC DEVICE,” which is a Continuation-in-Part and claims priority to U.S. application Ser. No. 12/939,077 (Docket No. 0036P/4954P), filed on Nov. 3, 2010, entitled “OPTOELECTRONIC DEVICES INCLUDING HETEROJUNCTION AND INTERMEDIATE LAYER”, and U.S. Pat. No. 8,937,244 (Docket No. 0004P/4933P), issued on Jan. 20, 2015, entitled “PHOTOVOLTAIC DEVICE”, and a Continuation-in-Part of U.S. patent application Ser. No. 14/846,675 (Docket No. 0076P/5453P), filed on Sep. 4, 2015, entitled “OPTOELECTRONIC DEVICE WITH DIELECTRIC LAYER AND METHOD OF MANUFACTURE”, which is a Continuation-in-Part and claims priority to U.S. patent application Ser. No. 12/904,047 (Docket No. 0019P/4962P), filed Oct. 13, 2010, entitled “TEXTURED METALLIC BACK REFLECTOR”, U.S. patent application Ser. No. 13/446,876 (Docket No. 0055P/5067P), filed Apr. 13, 2012, entitled “OPTOELECTRONIC DEVICE WITH NON-CONTINUOUS BACK CONTACTS”, U.S. Pat. No. 9,136,422 (Docket No. 0053P/5043P), issued on Sep. 15, 2015, entitled “TEXTURING A LAYER IN AN OPTOELECTRONIC DEVICE FOR IMPROVED ANGLE RANDOMIZATION OF LIGHT” and U.S. patent application Ser. No. 14/452,393 (Docket No. 0053CIP/5043CIP), filed on Aug. 5, 2014, entitled “THIN-FILM SEMICONDUCTOR OPTOELECTRONIC DEVICE WITH TEXTURED FRONT AND/OR BACK SURFACE PREPARED FROM TEMPLATE LAYER AND ETCHING”, which are incorporated herein by reference in their entirety.

### FIELD OF THE INVENTION

The present invention generally relates to optoelectronic semiconductor devices, and more particularly to optoelectronic devices with high band-gap absorbers and method of manufacturing the optoelectronic devices.

### BACKGROUND OF THE INVENTION

There is a need for providing optoelectronic devices that have increased efficiency when compared to conventional devices. Additionally, there is a move in modern consumer electronics to not have to plug consumer electronic devices into the wall for recharging. Also, there is increasing interest in finding ways to charge devices that require a small amount of power over a long period of time. Today that power is typically delivered by batteries but having to swap out batteries can be impractical or expensive in some applications. In particular, in an indoor setting there is a great potential to use room lighting to power certain devices. These optoelectronic devices should, however, be cost effective, easily implemented and adaptable to existing environments. Current solutions are not very efficient, and often not easy to integrate into the consumer electronic devices. The present invention addresses such a need.

### SUMMARY OF THE INVENTION

An optoelectronic device with at least one high band-gap absorber optimized for indoor use and a method of manufacturing the optoelectronic device are disclosed. The optoelectronic semiconductor device comprises a p-n structure made of one or more compound semiconductors, wherein the p-n structure comprises a base layer and an emitter layer, wherein the emitter and/or base layers comprise materials whose quantum efficiency spectrum is well-matched to a spectrum of incident light, wherein the incident light is from a light source other than the sun; and wherein the device is a flexible single-crystal device.

The method for forming an optoelectronic device optimized for the conversion of light from non-solar illumination sources into electricity, comprises depositing a buffer layer on a wafer; depositing a release layer above the buffer layer; depositing a p-n structure above the release layer; wherein the p-n structure comprises a base layer and an emitter layer, and wherein the emitter and/or base layers comprise materials whose quantum efficiency spectrum is well-matched to a spectrum of incident light, wherein the incident light is from a light source other than the sun; and lifting off the p-n structure from the wafer.

### BRIEF DESCRIPTION OF THE DRAWINGS

So that the manner in which the above recited features of the invention can be understood in detail, a more particular description of the invention, briefly summarized above, may be had by reference to the embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a diagram depicting light emission spectrum of various light sources, including high-efficiency light sources such as fluorescent lamps and light emitting diodes (LEDs).

FIG. 2 is a diagram depicting external quantum efficiency (EQE) for a typical thin film optoelectronic device comprising an AlGaAs or InGaP base layer before anti-reflection coating is applied.

FIG. 3 is a flow chart illustrating a process of forming an optoelectronic device comprising an AlGaAs or InGaP base layer and other semiconductor layers on a metal backing, all on a plastic support according to embodiments described herein.

FIG. 4 is a diagram depicting an optoelectronic device with an AlGaAs or InGaP base layer within the p-n structure and other semiconductor layers before the device is separated from the substrate.

FIG. 5 is a diagram depicting an optoelectronic device with front metal contacts after it is separated from the substrate according to an embodiment of the invention.

FIG. 6 depicts an optoelectronic device comprising an InGaP or AlGaAs absorber layer and other semiconductor layers on a metal backing, all on a plastic support and front and back metal contacts according to an embodiment of the invention.

### DETAILED DESCRIPTION

The present invention generally relates to optoelectronic semiconductor devices, and more particularly to optoelectronic devices with high band-gap absorbers and method of manufacturing the optoelectronic devices. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiments shown but is to be accorded the widest scope consistent with the principles and features described herein.

Embodiments of the inventions generally relate to optoelectronic devices and more particularly to optoelectronic devices with high band-gap absorbers and method of manufacturing the optoelectronic devices. Embodiments of the invention also relate to the fabrication of thin film devices, such as photovoltaic devices, light-emitting diodes, or other optoelectronic devices.

It is desirable to improve the performance of an optoelectronic device such as a photovoltaic cell or a light-emitting diode to improve the efficiency thereof without significantly affecting the cost or adding to overall size of the device. Additionally, there is a move in modern consumer electronics to not have to plug consumer electronics into the wall for recharging. Also, there is increasing interest in finding ways to charge devices that require a small amount of power over a long period of time. Today that power is typically delivered by batteries but having to swap out batteries can be impractical or expensive in some applications. In particular, in an indoor setting there is a great potential to use room lighting to power certain consumer electronic devices using indoor optoelectronic devices. These optoelectronic devices should, however, be cost effective, easily implemented and adaptable to existing environments. Current solutions are not very efficient, and often not easy to integrate into the consumer electronic devices. The present invention addresses such a need.

Generally, the performance of an optoelectronic device such as a photovoltaic cell or a light-emitting diode is improved by improving efficiency. High efficiency cells can be prepared by growing materials with different band-gap such that the highest band-gap material is on the light facing side and the lowest band gap material is on the opposite side. This results in the absorption of photons with different energy by different layers, improving the efficiency of the device since more photons are absorbed generating more current. This principle works well in case of solar cells under outdoor conditions where the incident light is mostly natural light from the Sun which is a combination of infrared, visible, ultraviolet light and radiant heat. However, the composition of indoor light which is mainly artificial light is different from the sunlight.

The present invention provides for a high efficiency optoelectronic device and a method of fabrication of the device, where the quantum efficiency spectrum of the device is well-matched to the visible spectrum of the high-efficiency light sources such as fluorescent lamps and LEDs for converting such artificial light into electricity.

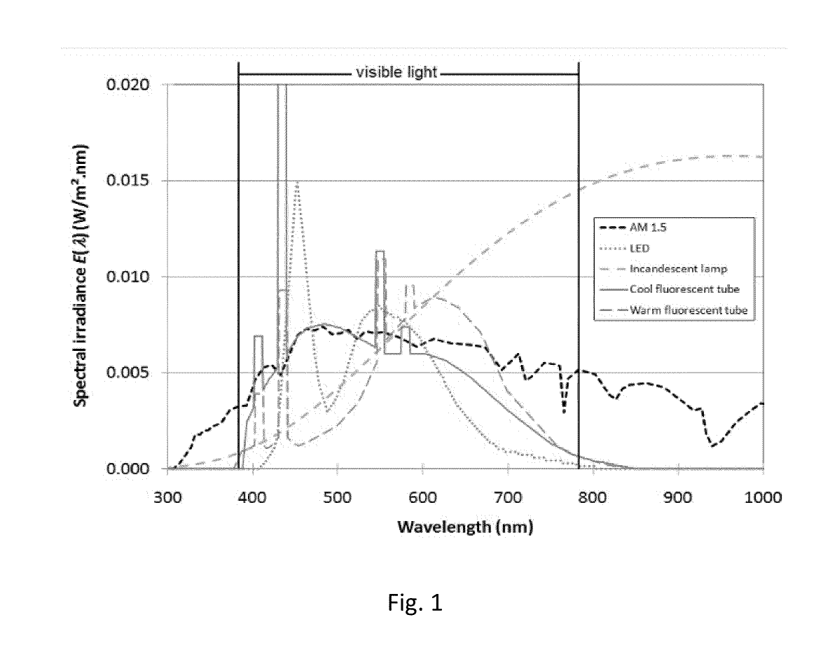

FIG. 1 is a diagram depicting light emission pattern of high-efficiency light sources such as fluorescent lamps and light emitting diodes (LEDs) (WHICH TYPE of solar cell is best for low power indoor devices? , B. Minnaert and P. Veelaert, Proceedings of Innovation for Sustainable Production conference 2010). High-efficiency light sources such as fluorescent lamps and LEDs gain their high efficiency in part because they emit light almost exclusively in the visible part of the spectrum and very little energy is wasted as infrared light. An optoelectronic device whose quantum efficiency spectrum is well-matched to the same visible spectrum will therefore be a very efficient device for converting such artificial light into electricity. For example, for optimal efficiency of conversion of visible light into electricity, a photovoltaic cell should have an absorber or base material with bandgap wavelength in the range 550 nm-800 nm, that is 1.55 eV to 2.25 eV.

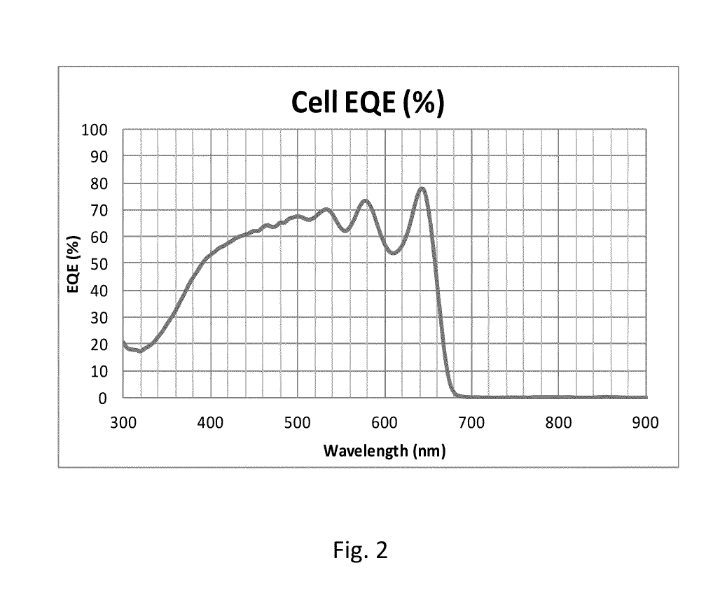

FIG. 2 is a diagram depicting external quantum efficiency (EQE) for an optoelectronic device comprising an AlGaAs or InGaP as a base layer before anti-reflection coating is applied, as measured at Alta Devices. An optoelectronic device has been demonstrated that comprises an AlGaAs or InGaP base layer and other semiconductor layers on a metal backing, all on a plastic support. Co-pending application Ser. No. 13/772,043 (Attorney Docket No. 0004C), entitled “PHOTOVOLTAIC DEVICE” which is incorporated herein in its entirety by reference describes the method of lifting off III-V devices into thin films, by the epitaxial liftoff process. This has now been applied to AlGaAs and InGaP devices with a metal backing, on a plastic support.

The bandgap of InGaP at a composition that is lattice-matched to GaAs (approximately In_{0.48}Ga_{0.52}P) is approximately 1.85-1.86 eV, leading to an absorption bandedge near 670 nm as shown in FIG. 2. The exact bandgap of the InGaP may depend on the degree of ordering in the crystal, but is generally within a range 1.84-1.91 eV. Similarly, the bandgap of AlGaAs is approximately 1.42-2.18 eV, depending on the concentration of Al in AlGaAs. The concentration of Al in AlGaAs can be adjusted such that the bandgap of AlGaAs is approximately 1.77-1.94, also leading to an absorption bandedge near 640-700 nm. For example the bandgap of Al_{0.37}Ga_{0.63}As is approximately the same as that of In_{0.48}Ga_{0.52}P, around 1.85-1.86 eV. Also, AlGaAs is approximately lattice-matched to GaAs at all compositions. This allows for potentially new applications using InGaP or AlGaAs as a base layer in combination with GaAs-based thin film technology.

One such application is as a red LED. The absorption bandedge also indicates the emission bandedge. When the device in FIG. 2 is pumped either optically or electrically, it emits light at wavelengths close to 680 nm, at the red end of the visible spectrum.

A second application is as a novel photovoltaic device, whose quantum efficiency spectrum is well-matched to the same visible spectrum will therefore be a very efficient device for converting that light into electricity. This device can be utilized with electronic devices in an indoor setting and/or as a mobile power device, better matched to modern lighting output spectra, enabling a very high efficiency, flexible, lightweight, mobile power conversion solution for powering next-generation consumer electronics for the convenience of not having to plug devices into the wall.

Many of the thin film devices described herein generally contain epitaxially grown layers which are formed on a sacrificial layer disposed on or over a support substrate or wafer. The thin film devices thus formed may be flexible single crystal devices. Once the thin film devices are formed by epitaxy processes, the thin film devices are subsequently separated from the support substrate or wafer, for example during an epitaxial lift off (ELO) process, a laser lift off (LLO) process, or a spalling process etc.

Herein, a layer can be described as being deposited “on or over” one or more other layers. This term indicates that the layer can be deposited directly on top of the other layer(s), or can indicate that one or more additional layers can be deposited between the layer and the other layer(s) in some embodiments. Also, the other layer(s) can be arranged in any order. To describe the features of the present invention in more detail refer now to the following discussion in conjunction with the accompanying figures.

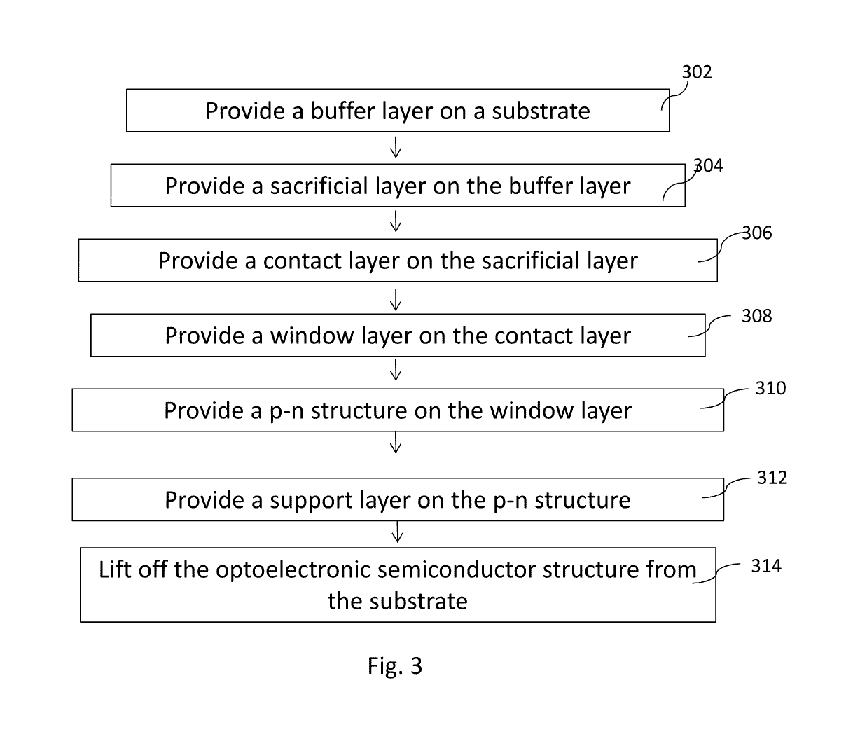

FIG. 3 is a flow chart illustrating a process of forming an optoelectronic device comprising an AlGaAs or InGaP base layer and other semiconductor layers on a support layer according to embodiments described herein. In an embodiment, the method comprises providing one or more buffer layers on a substrate via step 302. The purpose of the buffer layer(s) is to provide an intermediary between the substrate and the semiconductor layers of the final optoelectronic device that can accommodate their different crystallographic structures as the various epitaxial layers are formed. The buffer layer can also provide a more perfect surface (in terms of defect density, atomic flatness, etc.) for the subsequent layers to grow on than is provided by the substrate itself. Having a thickness of about 200 nm, for example, a buffer layer may comprise a group III-V compound semiconductor, such as gallium arsenide (GaAs), depending on the desired composition of the final optoelectronic device. For some embodiments, for example, the substrate may comprise GaAs when creating a GaAs buffer layer.

For some embodiments, a release layer also known as a sacrificial layer may be formed above the buffer layer via step 304 prior to deposition of the p-n structure, for example to enable liftoff of the p-n structure in an epitaxial liftoff (ELO) process. The sacrificial layer may comprise AlAs, AlGaAs, AlGaInP, or AlInP, or other layers with high Al content, or combinations thereof and is utilized to form a lattice structure for the layers contained within the cell, and then etched and removed during the ELO process. In other embodiments, alternative liftoff processes such as laser lift off (LLO), ion implantation and liftoff, liftoff by etching of a buried oxide layer or a buried porous layer, or spalling may be used. The sacrificial layer may have a thickness in a range from about 1 to 1000 nm, for example 1 to 100 nm.

Above the sacrificial layer, a contact layer may be formed via step 306. The contact layers can contain Group III-V materials, such as gallium arsenide (GaAs), depending on the desired composition of the final photovoltaic unit and may be doped or undoped. Some of the example embodiments include n-metal alloy contact, p-metal contact, n-metal contact, p-metal alloy contact, and layers suitable for use with contact layers of the cell are described in copending patent application Ser. No. 12/939,050, entitled, “Metallic Contacts for Photovoltaic Devices and Low-Temperature Fabrication Processes Thereof,” filed on Nov. 3, 2010, and which is incorporated herein by reference. Other types, structures, and materials of metal contact layers can also be used with the optoelectronic device 100.

In some embodiments, the doping concentration may be within a range greater than about 3×10¹⁸ cm⁻³, for example, from greater than about 5×10¹⁸ cm⁻³ to about 1×10¹⁹ cm⁻³. The high doping of the contact layers of the cell 300 allows an ohmic contact to be formed with a later-deposited metal layer without any annealing step performed to form such an ohmic contact.

In some embodiments, the contact layers may be gallium arsenide (GaAs) doped with silicon (Si). For example, some embodiments using a high-growth rate in forming the layers of the structure can use a silicon dopant (as an n-dopant) to bring the doping concentration to 5×10¹⁸ cm⁻³ or greater. For example, a precursor disilane can be introduced in a fast growth rate process to deposit the silicon. In other embodiments silane or ditertiarybutylsilane may be used as the silicon precursor. In other embodiments selenium (Se) or tellurium (Te) can be used as a dopant in the formation of the layers of structure. For example, Se may be supplied by a dimethyl selenide or diethyl selenide or di-isopropyl selenide or di-tert-butyl selenide or hydrogen selenide precursor; and Te may be supplied by a dimethyl telluride or diethyl telluride or di-isopropyl telluride precursor. In other embodiments, other n-type dopants or dopant precursors may be used. In other embodiments the contact layers are p-type and may be doped with carbon (C), zinc (Zn), magnesium (Mg), cadmium (Cd), or beryllium (Be). For example, C may be supplied by a carbon tetrabromide or carbon tetrachloride precursor; Zn may be supplied by a dimethyl zinc or diethyl zinc precursor; Mg may be supplied by a dimethyl magnesium or diethyl magnesium precursor; Cd may be supplied by a dimethyl cadmium or diethyl cadmium or methyl allyl cadmium precursor; and Be may be supplied by a dimethyl beryllium or diethyl beryllium or bismethylcyclopentadienyl-beryllium precursor. In other embodiments, other p-type dopants or dopant precursors may be used. In other embodiments, the contact layers may be aluminum gallium arsenide (AlGaAs).

The contact layers may be formed at a thickness of about 10 nm or greater, such as about 50 nm. In some embodiments, the contact layer 20 can be formed prior to an ELO process that separates the structure from the growth wafer. In some alternate embodiments, the contact layers can be formed at a later stage subsequent to such an ELO process.

Above the contact layer, a window layer may be formed via step 308. The window layer may comprise aluminum gallium arsenide (AlGaAs), such as Al_{0.35}Ga_{0.65}As, or may contain aluminum gallium indium phosphide (AlGaInP), such as Al_{0.3}Ga_{0.2}In_{0.5}P or Al_{0.3}Ga_{0.22}In_{0.48}P, or may contain aluminum indium phosphide (AlInP), such as Al_{0.5}In_{0.5}P or Al_{0.53}In_{0.47}P. The window layer may have a thickness in a range of about 5 to 50 nm (e.g., 20-35 nm) and may be doped or undoped. The window layer may be transparent to allow photons to pass through the window layer on the front side of the optoelectronic device to other underlying layers. The window layer may be lattice-matched to GaAs.

A p-n structure may be formed above the window layer via step 310. The absorber layer may comprise any suitable group III-V compound semiconductor with a specific band gap that specifically absorbs in the wavelength of interest. For example, AlGaAs or InGaP with a band gap of 1.42-2.18 eV, or more specifically in the range 1.77-1.94 eV. For example, a bandgap of 1.85-1.86eV absorbs light with wavelength less than approximately 670 nm, allowing for absorption of most of the light emitted by high-efficiency light sources such as fluorescent lamps and LEDs. P-n layers with absorber bandgaps of higher energy than this will tend to absorb less of the light generated by these high-efficiency light sources, while p-n layers with absorber bandgaps of lower energy than this will tend to produce a lower voltage when exposed to such a light source. Therefore, an absorber bandgap energy at the long wavelength (low energy) end of the emission spectrum of the light source to be absorbed can provide a good compromise of light absorption and voltage generation. The high-efficiency light sources such as fluorescent lamps and LEDs gain their high efficiency in part because they emit light almost exclusively in the visible part of the spectrum and very little energy is wasted as infrared light as shown in FIG. 1. A photovoltaic device comprising a group III-V compound semiconductor with a specific band gap whose quantum efficiency spectrum is well-matched to the same visible spectrum is therefore a very efficient device for converting that light into electricity.

In an embodiment, the p-n structure may be grown on a substrate, for example, a gallium arsenide wafer may be used, with epitaxially grown layers as thin films made of Group III-V materials. Alternatively a germanium wafer, or an indium phosphide wafer, or a sapphire wafer, or a gallium nitride wafer, or a silicon wafer may be used. The p-n structure may be formed by epitaxial growth using various techniques, for example, metalorganic chemical vapor deposition (MOCVD), molecular beam epitaxy (MBE), metalorganic vapor phase epitaxy (MOVPE or OMVPE), liquid phase epitaxy (LPE), hydride vapor phase epitaxy (HVPE), close-spaced vapor transport (CSVT) etc. In some embodiments the p-n structure is substantially a single crystal.

In some embodiments, the epitaxially grown layers of Group III-V materials can be formed using a high growth rate vapor deposition process. The high growth rate deposition process allows for growth rates of greater than 5 μm/hr, such as about 10 μm/hr or greater, or as high as about 100 μm/hr or greater. The high growth rate process includes heating a wafer to a deposition temperature of about 550° C. or greater, within a processing system, exposing the wafer to a deposition gas containing a chemical precursor, such as a group III-containing precursor gas and a group V-containing precursor gas, and depositing a layer containing a Group III-V material on the wafer. The group III-containing precursor gas may contain a group III element, such as indium, gallium, or aluminum. For example, the group III-containing precursor gas may be chosen from the list: trimethyl aluminum, triethyl aluminum, trimethyl gallium, triethyl gallium, trimethyl indium, triethyl indium, di-isopropylmethylindium, ethyldimethylindium. The group V-containing precursor gas may contain a group V element, such as nitrogen, phosphorus, arsenic, or antimony. For example, the group V-containing precursor gas may be chosen from the list: phenyl hydrazine, dimethylhydrazine, tertiarybutylamine, ammonia, phosphine, tertiarybutyl phosphine, bisphosphinoethane, arsine, tertiarybutyl arsine, monoethyl arsine, trimethyl arsine, trimethyl antimony, triethyl antimony, tri-isopropyl antimony, stibine.

The deposition processes for depositing or forming Group III-V materials, as described herein, can be conducted in various types of deposition chambers. For example, one continuous feed deposition chamber that may be utilized for growing, depositing, or otherwise forming Group III-V materials is described in the commonly assigned U.S. patent application Ser. Nos. 12/475,131 and 12/475,169, both filed on May 29, 2009, which are herein incorporated by reference in their entireties.

Some examples of layers usable in device and methods for forming such layers are disclosed in copending U.S. patent application Ser. No. 12/939,077, filed Nov. 3, 2010, and incorporated herein by reference in its entirety.

The p-n structure may contain various arsenide, nitride, and phosphide layers, such as but not limited to GaAs, AlGaAs, InGaP, InGaAs, AlInGaP, AlInGaAs, InGaAsP, AlInGaAsP, GaN, InGaN, AlGaN, AlInGaN, GaP, alloys thereof, derivatives thereof and combinations thereof. In general, the p-n structure comprises a Group III-V semiconductor and includes at least one of the group consisting of: gallium, aluminum, indium, phosphorus, nitrogen, and arsenic. In one embodiment the p-n structure comprises gallium arsenide material, and derivatives thereof.

For example, in one embodiment the p-n structure comprises a p-type aluminum gallium arsenide layer or stack disposed above an n-type aluminum gallium arsenide layer or stack. In one example, the p-type aluminum gallium arsenide stack has a thickness within a range from about 100 nm to about 3,000 nm and the n-type aluminum gallium arsenide stack has a thickness within a range from about 100 nm to about 3,000 nm. In one example, the n-type aluminum gallium arsenide stack has a thickness within a range from about 100 nm to about 2500 nm. Suitable n-type and p-type dopants are listed above.

In another embodiment, the p-n structure comprises indium gallium phosphide material, and derivatives thereof. The indium gallium phosphide material may contain various indium gallium phosphide layers, such as an indium gallium phosphide, aluminum indium gallium phosphide, etc. For example, in one embodiment the p-n structure comprises a p-type aluminum indium gallium phosphide layer or stack disposed above an n-type indium gallium phosphide layer or stack.

In one example, the p-type aluminum indium gallium phosphide stack has a thickness within a range from about 100 nm to about 3,000 nm and the n-type indium gallium phosphide stack has a thickness within a range from about 100 nm to about 3,000 nm. In one example, the n-type indium gallium phosphide stack has a thickness within a range from about 100 nm to about 1,500 nm.

In another embodiment, the p-n structure comprises indium gallium arsenide phosphide material, and derivatives thereof. The indium gallium arsenide phosphide material may contain various indium gallium arsenide phosphide layers, such as an indium gallium phosphide, aluminum indium gallium phosphide, indium gallium arsenide phosphide, aluminum indium gallium arsenide phosphide etc. For example, in one embodiment the p-n structure comprises a p-type aluminum indium gallium phosphide layer or stack disposed above an n-type indium gallium arsenide phosphide layer or stack.

In another embodiment, the p-n structure comprises aluminum indium gallium phosphide material, and derivatives thereof. The aluminum indium gallium phosphide material may contain various aluminum indium gallium phosphide layers, such as an aluminum indium phosphide, aluminum indium gallium phosphide, etc. For example, in one embodiment the p-n structure comprises a p-type aluminum indium phosphide layer or stack disposed above an n-type aluminum indium gallium phosphide layer or stack.

Furthermore, the junction formed between the two layers can be a heterojunction that is, the N-layer and P-layer could be of different material (the N-layer being InGaP and the P-layer being AlGaAs, for example), or a homojunction, that is, both the N-layer and P-layer could be the same material (both layers being AlGaAs or both layers InGaP, for example) and that would be within the spirit and scope of the present invention. Also the p-n structure could have either doping polarity, with n-type material at the top of the device and p-type material at the bottom, or alternatively with p-type material at the top of the device and n-type material at the bottom. Furthermore, the optoelectronic device could be comprised of multiple p-n layers grown in series, for example, to form a multijunction photovoltaic cell.

For example, in one embodiment the p-n structure comprises a p-type aluminum gallium arsenide layer or stack disposed above an n-type indium gallium phosphide layer or stack. In one example, the p-type aluminum gallium arsenide stack has a thickness within a range from about 100 nm to about 3,000 nm and the n-type indium gallium phosphide stack has a thickness within a range from about 100 nm to about 3,000 nm. In one example, the n-type aluminum gallium arsenide stack has a thickness within a range from about 50 nm to about 400 nm, for example approximately 100 nm.

The p-n structure may be monocrystalline. It may comprise an emitter and a base layer. The emitter may be deposited first, or the base layer may be deposited first. The emitter and base may be of opposite doping types, forming a p-n junction. The p-n junction may be a heterojunction or a homojunction, that is the material of the base may be the same as or different from the material of the emitter. Furthermore, the p-n junction may be closer to the interface between the window layer and the p-n structure than it is to the interface between p-n structure and the support layer. In other embodiments the p-n junction may be closer to the interface between p-n structure and the support layer than it is to the interface between the window layer and the p-n structure.

The emitter layer may be n-doped, and for some embodiments, the doping concentration of the n-doped emitter layer may be in a range from about 1×10¹⁶ to 1×10²⁰ cm⁻³ (e.g., 2×10¹⁷ cm⁻³). The thickness of the emitter layer may be in a range from about 100 to 3500 nm. In other embodiments the emitter may be p-type, with doping in the range 1×10¹⁷ to 1×10²⁰ cm⁻³.

The base layer may be monocrystalline. The base layer may be heavily p-doped (i.e., p⁺-doped), and for some embodiments, the doping concentration of the p⁺-doped base layer may be in a range from about 1×10¹⁷ to 1×10²⁰ cm⁻³ (e.g., 3×10¹⁸ cm⁻³). The thickness of the base layer 110 may be about 100 nm-3500 nm, for example. In other embodiments the base may be n-type, with doping in the range 1×10¹⁷ to 1×10²⁰ cm⁻³.

The contact of an n-doped emitter layer to a p-doped base layer creates a p-n layer. Alternatively, the contact of a p-doped emitter layer to an n-doped base layer also creates a p-n layer. When light is absorbed near the p-n layer to produce electron-hole pairs, the built-in electric field may force the holes to the pt-doped side and the electrons to the n-doped side. This displacement of free charges results in a voltage difference between the two layers, such that electron current may flow when a load is connected across terminals coupled to these layers.

The base layer is typically p-doped in conventional devices due to the diffusion length of the carriers. Fabricating a thinner base layer according to embodiments of the invention allows for the change to an n-doped base layer.

The thickness and doping of the emitter must be designed and controlled such that adequate lateral conductivity is present to allow for current collection within the device, while retaining adequate minority carrier transport for light-generated carriers within the emitter. The higher mobility of electrons in an n-doped layer compared to the mobility of holes in a p-doped layer allows for an emitter that is of lower doping density, and/or is thinner, in the n-doped emitter layer of embodiments of the invention.

For some embodiments, an interface or intermediate layer may be formed between the emitter layer and the base layer. The interface layer may comprise any suitable group III-V compound semiconductor, such as GaAs, AlGaAs, InGaP, AlInGaP, or a combination thereof. The interface layer may be n-doped, p-doped, or not intentionally doped. The thickness of the interface layer may be about 5-200 nm, for example. The intermediate layer is located between the p-doped layer and the n-doped layer, and may be comprised of the same material as either the n-doped layer or the p-doped layer, or being comprised of a different material, or being a layer of graded composition. The intermediate layer thus formed may provide a location offset for one or more heterojunction from its corresponding p-n junction. Such an offset may allow for reduced dark current within the device, improving its performance.

In some embodiments, the p-n structure may comprise a textured surface. This textured surface can improve the scattering of light at that surface, as well as improve adhesion to both metal and dielectric layers. In some embodiments, the texturing is achieved during the growth of the materials that comprise the p-n structure. This may be achieved at least in part for by exploiting a lattice mismatch between at least two materials in the p-n structure, for example in a Stranski-Krastanov process or a Volmer-Weber process. In another embodiment, a layer in or on the p-n structure may act as an etch mask and texturing can be provided by an etching process. In yet another embodiment, texturing may be provided by physical abrasion such as sandpaper or sandblasting or particle blasting or similar processes.

In addition, in an embodiment, the back side and/or the front side of the p-n structure can be textured to improve light scattering into and/or out of the device.

A support layer may then be deposited on the p-n structure thus formed via step 312. The support layer may comprise any of a diffuser layer, a dielectric layer, a semiconductor contact layer, a passivation layer, a transparent conductive oxide layer, an anti-reflective coating, a metal coating, an adhesive layer, an epoxy layer, plastic coating and a combination thereof.

A diffuser layer may be deposited on the p-n structure. The diffuser layer covered with a reflective layer provide for the photons to be redirected to the base layer to be absorbed and converted into electrical energy.

A dielectric layer may be patterned on the p-n structure, providing one or more openings for electrical contacts. In one embodiment, a dielectric layer with an array of openings is disposed on a p-n structure, forming a plurality of apertures extending into the p-n structure. In an embodiment, the openings for electrical contacts may be patterned such that front metal contacts and openings for electrical contact to back metal layer are offset to prevent short circuits. In another embodiment, the front and back metal contacts may be aligned.

In an embodiment, the dielectric layer is disposed by using various methods such as but not limited to spin coating, dip coating, spray coating, physical vapor deposition (PVD) (including sputtering, evaporation, and electron-beam evaporation, etc.), chemical vapor deposition (CVD) (including metalorganic chemical vapor deposition (MOCVD), atmospheric pressure chemical vapor deposition (APCVD), low pressure chemical vapor deposition (LPCVD), plasma-enhanced chemical vapor deposition (PECVD), ion-beam assisted chemical vapor deposition (IBAD CVD), etc.), atomic layer deposition (ALD), powder coating, sol gel, chemical bath deposition (CBD), close space sublimation (CSS), inkjet printing, screen printing and lamination. The patterning of the dielectric layer can achieved either directly during the dielectric disposition process, for example in a printing process or by using a shadow mask, or indirectly in a process subsequent to the disposition process by using various techniques comprising wet or dry etching through the dielectric layer, patterning the dielectric layer using photolithography, electron-beam lithography, imprint lithography, and laser ablation etc.

What is meant by “directly patterning” is that the pattern is provided during the dielectric deposition in an additive process, without the need for a subsequent subtractive step to remove significant amounts of dielectric to form the pattern, for example using inkjet printing, shadow masking, or screen printing, etc. What is meant by “indirect patterning” is that there is a patterning step subsequent to the dielectric deposition step, usually in a subtractive process or combination of processes, such as in wet or dry etching, photolithography, electron-beam lithography, imprint lithography, or laser ablation, etc.

For depositing a dielectric layer using an inkjet printing technique, a dielectric material of specific viscosity and drying properties is used such that the dielectric material is liquid during the application process and becomes solid after optional curing. Depending on the properties of the dielectric material used, it can be cured at elevated temperature or under ultraviolet light if required, or simply at room temperature, for example by evaporation of solvent components in the dielectric material. If the dielectric material used is photosensitive it may be cured using light and if the dielectric material used is not photosensitive it may be cured using heat. For some dielectric materials a combination of light and heat may be used for curing.

The dielectric layer may have a thickness within a range from about 10 nm to about 10 μm, preferably, from about 20 nm to about 2000 nm, and more preferably, from about 50 nm to about 1000 nm. In some embodiments, the thickness of the dielectric layer may differ substantially based on the technique used for deposition of the dielectric layer. For example, the thickness of the dielectric layer deposited using screen printing may be different from that deposited using inkjet printing. For example, typical film thickness obtained using inkjet printing after curing is in the range of about 10 nm to about 10 μm, more typically in the range of about 100 nm to about 1000 nm, more typically about 500 nm. Thinner layers are generally harder to control as they require better control of the spreading.

In some embodiments, the dielectric layer has openings to provide for electrical connection between layers above and below the dielectric. Each opening within the dielectric layer may have a diameter within a range from about 5 μ to about 1000 μm, and preferably from about 20 μm to about 500 μm. Typical via width obtained by inkjet printing is in the range of about 10 μm to about 1000 μm, for example 50 μm-500 μm, and more typically 60 μm-250 μm. Smaller via width is generally preferred but is generally harder to control. In other embodiments the dielectric layer has no openings and an electrical connection is provided by the dielectric layer itself.

The dielectric layer comprises dielectric material, wherein the dielectric material is chemically resistant to acids to etching by acids such as hydrochloric acid, sulfuric acid or hydrofluoric acid, for example during an epitaxial lift off (ELO) process. The dielectric materials can also be transparent and provide adhesion to both metal and semiconductor layers. The dielectric materials can also be electrically insulating or electrically conducting. The organic dielectric materials may comprise any of polyolefin, polycarbonate, polyester, epoxy, fluoropolymer, derivatives thereof and combinations thereof. The inorganic dielectric materials may comprise any of arsenic trisulfide, arsenic selenide, a-alumina (sapphire), magnesium fluoride, calcium fluoride, diamond, derivatives thereof and combinations thereof.

In some embodiments, the dielectric layer contains a dielectric material with a refractive index within a range from about 1 to about 3. In an embodiment, the dielectric layer can be physically or optically textured. The physical and/or optical texture may be provided by embedding particles within the dielectric material. In this embodiment, the dielectric material comprises particles such as alumina, titania, silica or combinations thereof, to scatter light, disposed on a p-n structure.

In an embodiment, the dielectric layer contains a dielectric material whose coefficient of thermal expansion (CTE) is similar to that of the Group III-V semiconductor onto which it is disposed. In another embodiment the CTE of the dielectric materials in the dielectric layer are dissimilar from that of the Group III-V semiconductor onto which they are disposed.

In another embodiment, the dielectric layer comprises a textured surface to scatter light and improve adhesion to both metal and semiconductor layers. Texturing of the dielectric surface can be achieved by particle or other mask deposition followed by etching, particle blasting, mechanical imprinting such as imprint lithography or stamping, laser ablation, wet etching or dry etching.

In another embodiment, the dielectric layer comprises a surface diffraction grating to disperse light. The pitch and facet profile of the surface diffraction grating is chosen such that at the band gap wavelength: 1. Zeroth order diffraction is minimized and 2. First order diffraction angle is higher than the angle of total internal reflection. The diffraction grating with increased angle allows more light to be diffracted into the optoelectronic device. Grating of the dielectric surface may be accomplished by mechanical imprinting such as but not limited to imprint lithography, imprint stamping or laser ablation. Alternatively, other techniques such as photolithography, electron-beam lithography, interference lithography, etc. may be used.

Adhesion between the p-n structure and the dielectric material can be improved by texturing the p-n structure or the dielectric layer as described above, or chemically, for example with alkylphosphonate monolayers or derivatives thereof. The adhesion layer may have a thickness within a range from about a monolayer to about 100 Å. The dielectric adhesion layer may be deposited by a variety of techniques including, but not limited to, atomic layer deposition (ALD), spincoating, inkjetting, chemical bath deposition (CBD) or dipcoating techniques.

Referring again back to FIG. 3, a metallic layer is then disposed on the dielectric layer. In some embodiments, in which the dielectric layer has been provided with openings, the metallic layer makes one or more contacts with the p-n structure through these openings.

The metallic layer may contain at least one metal, such as silver, gold, aluminum, nickel, copper, platinum, palladium, molybdenum, tungsten, titanium, chromium, alloys thereof, derivatives thereof, and combinations thereof. In specific examples, the metallic layer may contain silver, copper, or gold. The metallic layer may have a thickness within a range from about 1 nm to about 10,000 nm, preferably, from about 10 nm to about 4000 nm.

In an embodiment, the metallic layer may comprise one or more layers made of the same or different metals. For example, the metallic layer may comprise an adhesion layer comprising materials such as but not limited to nickel, molybdenum, tungsten, titanium, chromium, palladium, alloys thereof, derivatives thereof, or combinations thereof with a thickness less than 100 nm, and preferably less than 20 nm, along with a reflector layer comprising materials such as but not limited to silver, gold, aluminum, copper, platinum, alloys thereof, derivatives thereof, or combinations thereof with a thickness more than 50 nm.

Additional metallic layers may be also deposited, for example to improve the electrical or mechanical properties of the combination of metal layers, and may comprise a back metal with varying thickness. In another embodiment, metallic contacts may be formed separately from the metallic layer. For example the metal in the apertures in the dielectric may be deposited prior to the dielectric deposition or prior to the metal reflector.

In an embodiment, the metallic layer comprises a metallic reflector layer disposed on or over the dielectric layer, and a plurality of reflector protrusions formed within the dielectric layer extending from the metallic reflector layer and into the p-n structure. In an embodiment, the metallic reflector layer may be textured. The metallic reflector layer thus formed may be on the back side of the optoelectronic device. For example, if the optoelectronic device is a photovoltaic device, the metallic reflector may be on the side of the device away from incident light.

The metallic reflector may contain at least one metal, such as silver, gold, aluminum, nickel, copper, platinum, palladium, alloys thereof, derivatives thereof, and combinations thereof. In specific examples, the metallic reflector layer may contain silver, copper, aluminum, platinum, or gold, alloys thereof, derivatives thereof, or combinations thereof. The metallic reflector layer may have a thickness within a range from about 1 nm to about 10,000 nm or greater. In some examples, the thickness of the metallic reflector layer may be from about 10 nm to about 4000 nm.

Similarly, the reflector protrusions contain at least one metal, such as silver, gold, aluminum, nickel, copper, platinum, palladium, molybdenum, tungsten, titanium, chromium, alloys thereof, derivatives thereof, and combinations thereof. In specific examples, the reflector protrusions may contain silver, copper, or gold. Each protrusion may have a diameter within a range from about 5 μm to about 100 μm, and preferably from about 50 μm to about 500 μm. Each protrusion may have a length within a range from about 10 nm to about 10 μm, such as from about 50 nm to about 1000 nm. In some embodiments the reflector protrusion diameter or length may be defined by the vias in the dielectric, and the dielectric layer thickness, respectively.

In an embodiment, under the reflector protrusions there is an adhesion layer comprising materials such as but not limited to nickel, molybdenum, tungsten, titanium, chromium, palladium, alloys thereof, derivatives thereof, or combinations thereof. The adhesion layer may have a thickness within a range from about 1 Å to about 100 nm. The metallic adhesion layer may be deposited by a variety of techniques including, but not limited to, PVD (including evaporation and sputtering for example), electroless plating, electroplating, ALD, or CVD techniques.

In an embodiment, above the metallic layer are additional layers such as an adhesive, resin, epoxy, acrylic, polyurethane, polyester, polyester-epoxy blend and/or glue layer and above that layer there may be a carrier layer such as a plastic or wax or rubber or other polymer such as a polyethylene, polyester, polyolefin, polyethylene terephthalate (PET), polyethylene naphthalate (PEN), and/or polyimide layer, derivatives thereof, or combinations thereof. This can act as a handle material to hold the p-n structure, dielectric layer, and metal layer after a lift off step such as epitaxial liftoff (ELO). The mechanical properties of the adhesive and carrier layers may also affect the liftoff process itself, for example by affecting the overall stiffness of the combined handle, adhesive, p-n structure, dielectric layer, and metal layer structure during the liftoff. The carrier layer may also be flexible.

Referring back to FIG. 3, the p-n structure, the optional dielectric layer, the metal layer and the plastic handle are then lifted off the substrate, via step 314. In some embodiments a thin film optoelectronic device may be subsequently removed from a support substrate or wafer, for example during an epitaxial lift off (ELO) process, a laser lift off (LLO) process, ion implantation and liftoff, liftoff by etching of a buried oxide layer or a buried porous layer, or a spalling process etc., where the thin film optoelectronic device compromises the p-n structure, the dielectric layer, and the metal layer. The thin film optoelectronic devices thus formed may be flexible, single crystal devices.

In an embodiment, the functional layers of the optoelectronic device (e.g., the window layer, the base layer, and the emitter layer) may be separated from the buffer layer(s) and substrate during the epitaxial lift-off (ELO) process by immersing the resulting structure comprising the p-n structure, the dielectric layer and the metal layer is in hydrofluoric acid (HF) and sacrificing the thin sacrificial layer via step 314 by selectively etching AlAs release layer with aqueous HF, leaving a flexible, thin film, AlGaAs or InGaP-based device.

The combination of highly reflective back contact layer comprising a dielectric layer and the epitaxial lift-off process reduces dark current in the resulting device producing highly efficient single crystal, flexible optoelectronic device.

In an embodiment, the optoelectronic device can include a plurality of non-continuous metal contacts that improve the reflectivity and reduce the power losses associated with the configuration of the back surface of the device. By reducing the amount of metal in direct contact with the semiconductor, plasmonic losses at the back contact are reduced, improving the angle-averaged reflectivity of the back contact, which in turn increases the minority carrier density in the device under illumination, improving the external fluorescence of the device and reducing the loss of recycled band edge photons within the device. These features are of particular importance in a photovoltaic cell and for light-emitting diode (LED) applications. For example, in a photovoltaic cell, a dielectric reflector may increase the open-circuit and operating voltage of the device. Accordingly, described below in conjunction with the accompanying figures are multiple embodiments of an optoelectronic device which utilizes such contacts.

By “non-continuous” metal contacts it is not necessarily implied that the metal contacts are disconnected. The metal contacts could be all connected together, or they could be disconnected. The metal contacts may be disconnected in this sense if for example there is an array of separate contacts between the metal and the p-n structure. The metal contacts may be connected in this sense if for example there is a connected “finger” pattern where the metal connects to the p-n structure, such that metal does not contact the entirety of the p-n structure surface. The metal may also be connected to each other through the metallic layer itself. The front metal contacts may be non-continuous yet connected, in that they do not cover the entire front surface of the device (which would block the incident sunlight in the case of a photovoltaic cell, or the exiting light in the case of an LED), and yet are connected such that power can be input or extracted by making contact to a single point on the top metal of the device (in addition to making connection to the back of the device).

The non-continuous metal contacts in any of the above mentioned embodiments can be arranged such that there is no alignment (in the sense of an imaginary perpendicular line drawn directly through the device) between the contacts on the top of the device and the plurality of non-continuous metal contacts directly adjacent to the p-n structure material on the back of the device. Alternatively there may be some area of alignment, but reduced relative to the total area of the front metal. In some embodiments, there may still be alignment between the front metal and the back mirror or the reflective metal, but there may be a dielectric between them. In other embodiments there is no back mirror metal. In either case, this can provide an additional advantage in that the chance of a metal-on-metal short, either during device fabrication or after the device has aged, can be greatly reduced. This can improve manufacturing yield and product reliability. In other embodiments the degree of alignment between back metal and front metal is substantially unchanged.

Finally, it is well understood by those of ordinary skill in the art that additional layers could exist either on top of the structures shown, or underneath them. For example, underneath the reflector metal there could be other support layers such as metals, polymers, glasses, or any combination thereof.

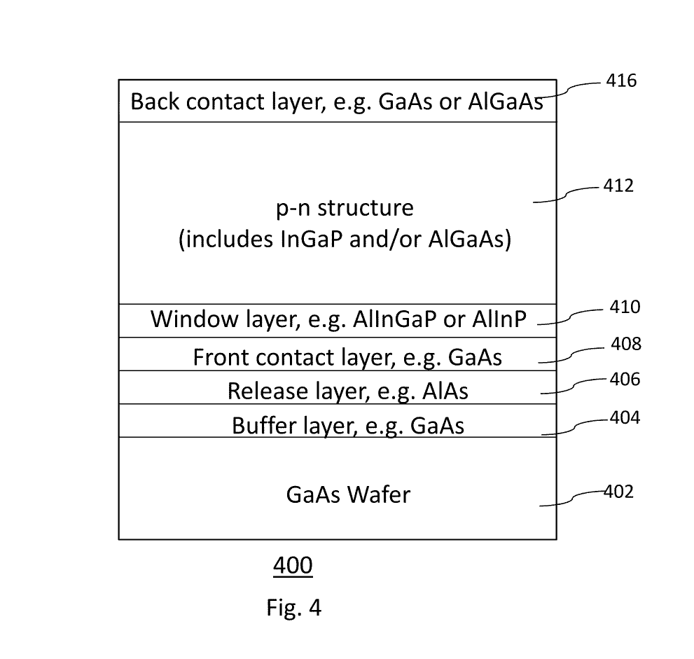

FIG. 4 is a diagram depicting an optoelectronic device with an AlGaAs or InGaP absorber layer (p-n structure) and other semiconductor layers before the device is separated from the substrate. The optoelectronic device 400 comprises epitaxially grown semiconductor layers on a substrate 402 such as GaAs wafer. The optoelectronic device 400 comprises a buffer layer 404 deposited on the substrate 402, a release layer 406 deposited on the buffer layer 404, a contact layer 408 deposited on the release layer 406 followed by a window layer 410. The optoelectronic device 400 further comprises a p-n structure 412, and a back contact layer 416 deposited on the window layer 410. In an embodiment, the optoelectronic device thus formed may also include optional support layers comprising any of a diffuser layer, a dielectric layer, a semiconductor contact layer, a passivation layer, a transparent conductive oxide layer, an anti-reflective coating, a metal coating, an adhesive layer, an epoxy layer, plastic coating and a combination thereof.

In some embodiments, the p-n structure 412 may comprise an emitter and a base layer, of opposite doping types, and these may form a p-n junction. In some embodiments the p-n junction may be closer to the window layer 410 than it is to the back contact layer 416. In other embodiments the p-n junction may be closer to the back contact layer 416 than it is to the window layer 410. In other embodiments the p-n junction may be equidistant from both the window layer 410 and the back contact layer 416.

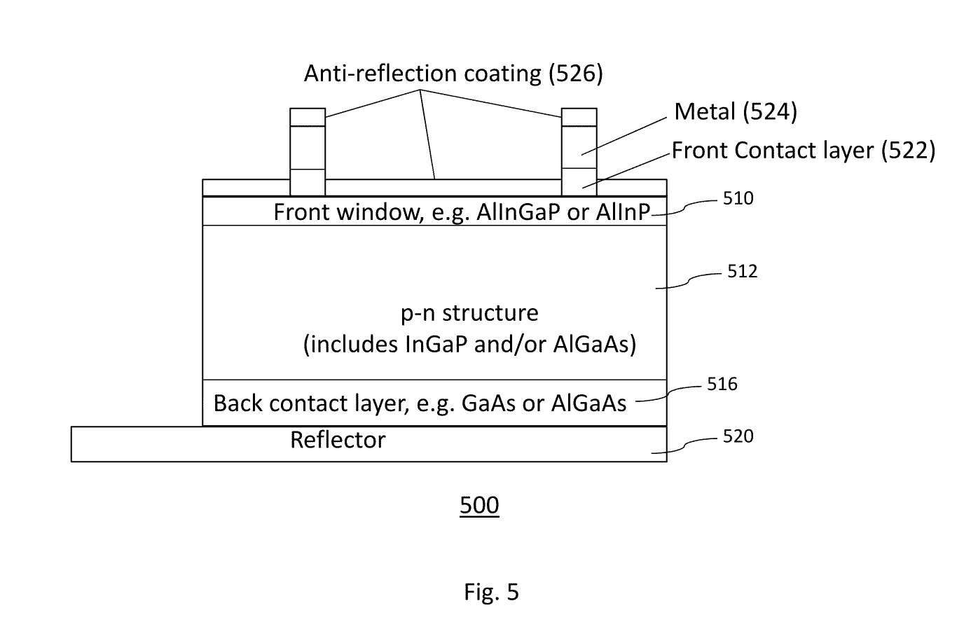

FIG. 5 depicts an optoelectronic device with front metal contacts after it is separated from the substrate according to an embodiment of the invention comprising an optional reflector layer 520. As shown in FIG. 5, a contact layer 522 is disposed on a front window layer 510. Once the device is separated from the growth substrate, a metallic layer is disposed on top of the front contact layer 522 forming front metal contacts 524. In an embodiment, an anti-reflection coating (ARC) 526 may be deposited on the optoelectronic device. In an embodiment, the optoelectronic device thus formed may also include optional support layers comprising any of a diffuser layer, a dielectric layer, a semiconductor contact layer, a passivation layer, a transparent conductive oxide layer, an anti-reflective coating, a metal coating, an adhesive layer, an epoxy layer, plastic coating or a combination thereof.

In an embodiment, the front metal contacts can be deposited on the optoelectronic device before or after the device is separated from the substrate. In another embodiment, additional layers can be deposited on the optoelectronic device before or after the device is separated from the substrate.

As described above, the p-n structure 512 may comprise an emitter and a base layer, of opposite doping types, and these may form a p-n junction. In some embodiments the p-n junction may be closer to the window layer 510 than it is to the back contact layer 516. This is called a front junction (FJ) optoelectronic device. In other embodiments the p-n junction may be closer to the back contact layer 516 than it is to the window layer 510. This is called a rear junction (RJ) optoelectronic device. In other embodiments the p-n junction may be equidistant from both the window layer 510 and the back contact layer 516. Furthermore, the p-n junction could be either a homojunction or a heterojunction in either the FJ or RJ embodiments.

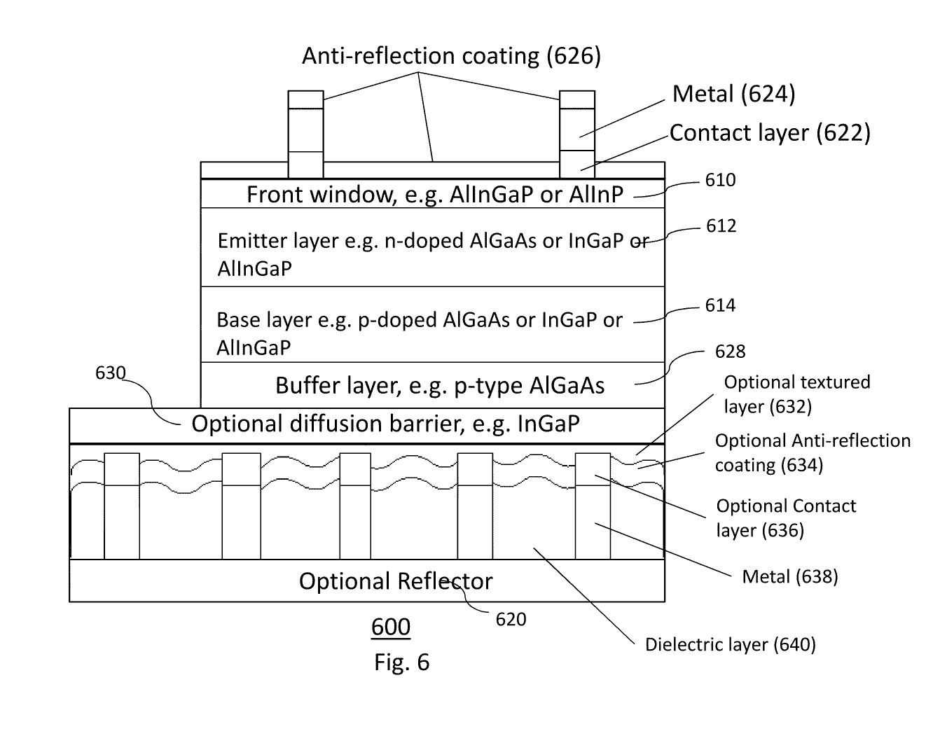

FIG. 6 depicts an optoelectronic device comprising an InGaP or AlGaAs absorber layer and other semiconductor layers on a metal backing, all on a plastic support and front and back metal contacts according to an embodiment of the invention. As shown in FIG. 6, a contact layer 622 is disposed on a front window layer 610. A metallic layer is then disposed on top of the contact layer 622 forming front metal contacts 624. In some embodiments the front metal contacts 624 are arranged such that there is no alignment (in the sense of an imaginary perpendicular line drawn directly through the device) between the front metal contacts 624 on the top of the device and the plurality of non-continuous metal contacts directly adjacent to the p-n structure material on the back of the device as illustrated by metal protrusions formed through openings 638. In another embodiment, the front and back metal contacts may be aligned. Optionally, an anti-reflection coating (ARC) 626 may be deposited on the optoelectronic device.

In an embodiment, the front and/or back metal contacts can be deposited on the optoelectronic device before or after the device is separated from the substrate. In another embodiment, additional layers can be deposited on the optoelectronic device before or after the device is separated from the substrate. One of ordinary skill in the art readily recognizes that a variety of materials listed could differ from the examples listed herein. As already described above, in some embodiments the interface between the emitter layer 612 and the base layer 614 may be closer to the front window 610 than it is to the buffer layer 628 (an FJ optoelectronic device as described above). In other embodiments the interface between the emitter layer 612 and the base layer 614 may be closer to the buffer layer 628 than it is to the front window 610 (an RJ optoelectronic device as described above). Furthermore, the p-n junction formed in structure 600 could be a homojunction or a heterojunction, that is, both the n-layer 612 and p-layer 614 could be the same material (for example both InGaP or both AlGaAs), or could be different materials (for example, InGaP emitter and AlInGaP base, or InGaP emitter and AlGaAs base), and that would be within the spirit and scope of the present invention. Also, both layers 612 and 614 could contain the same elements but in different proportions, for example, both layers could be AlGaAs or both layers could be AlInGaP, but with different fractions of Al. Also the doping could be inverted, with p-type material at the top of the device, facing the light source, and n-type material at the bottom. One or more additional p-n structures could be added to structure 600 in a similar fashion, either above or below structure 600, and could be possibly coupled to the rest of the device through a tunnel junction layer or layers.

What is claimed is:

1. An optoelectronic semiconductor device, comprising:
a p-n structure comprising one or more compound semiconductors,
wherein the p-n structure comprises a base layer and an emitter layer,
wherein any of the emitter layer, the base layer or a combination thereof comprises a material whose quantum efficiency spectrum is well-matched to a spectrum of incident light, wherein the incident light is from a light source other than the sun; and
wherein the device is a flexible single-crystal device.

2. The optoelectronic device of claim 1, having a first side and a second side, wherein the first side of the device is a back side of the device and the second side of the device is a front side of the device, and wherein the device is configured to receive the incident light on the second side of the device.

3. The optoelectronic device of claim 2, wherein a p-n junction is formed between the base layer and the emitter layer.

4. The optoelectronic device of claim 1, wherein the emitter layer and the base layer are made of the same material, such that a homojunction is formed between the emitter layer and the base layer.

5. The optoelectronic device of claim 1, wherein the emitter layer is made of a different material than the base layer, such that a heterojunction is formed between the emitter layer and the base layer.

6. The optoelectronic device of claim 3, wherein the p-n junction is closer to the second side of the device than it is to the first side of the device.

7. The optoelectronic device of claim 3, wherein the p-n junction is closer to the first side of the device than it is to the second side of the device.

8. The optoelectronic device of claim 2, further comprising a front contact layer and a window layer closer to the second side of the device.

9. The optoelectronic device of claim 2, wherein an antireflective coating is disposed above the window layer closer to the second side of the device.

10. The optoelectronic device of claim 2, further comprising a support layer, wherein the support layer comprises any of a diffuser layer, a dielectric layer, a semiconductor contact layer, a passivation layer, a transparent conductive oxide layer, an anti-reflective coating, a metal coating, an adhesive layer, an epoxy layer, plastic coating or a combination thereof, and the support layer is closer to the first side of the device than the p-n structure is to the first side of the device.

11. The optoelectronic device of claim 10, wherein the diffuser is disposed below the p-n structure, closer to the first side of the device than the p-n structure is to the first side of the device, wherein the diffuser is covered with a reflector layer which provides for photons to be redirected to the base layer to be absorbed and converted into electric energy.

12. The optoelectronic device of claim 10, wherein the dielectric layer comprises dielectric materials that are resistant to etching by acids such as hydrochloric acid, sulfuric acid or hydrofluoric acid during an epitaxial lift off (ELO) process.

13. The optoelectronic device of claim 10, wherein the metal coating further comprises a metallic reflector layer.

14. A method for forming an optoelectronic device optimized for the conversion of light from non-solar illumination sources into electricity, comprising:
depositing a buffer layer on a wafer;
depositing a release layer above the buffer layer;
depositing a p-n structure above the release layer;
wherein the p-n structure comprises a base layer and an emitter layer, and
wherein any of the emitter layer, the base layer or a combination thereof comprises a material whose quantum efficiency spectrum is well-matched to a spectrum of incident light, wherein the incident light is from a light source other than the sun; and
lifting off the p-n structure from the wafer.

15. The method of claim 14, wherein the optoelectronic device comprises a first side and a second side, wherein the first side of the device is a back side of the device and the second side of the device is a front side of the device, and wherein the device is configured to receive the incident light on the second side of the device.

16. The optoelectronic device of claim 15, wherein a p-n junction is formed between the base layer and the emitter layer.

17. The method of claim 14, wherein the emitter layer and the base layer are made of the same material, such that a homojunction is formed between the emitter layer and the base layer.

18. The method of claim 14, wherein the emitter layer is made of a different material than the base layer, such that a heterojunction is formed between the emitter layer and the base layer.

19. The method of claim 16, wherein the p-n junction is closer to the second side of the device than it is to the first side of the device.

20. The method of claim 16, wherein the p-n junction is closer to the first side of the device than it is to the second side of the device.

21. The method of claim 15, wherein the optoelectronic device further comprises a front contact layer and a window layer closer to the second side of the device.

22. The method of claim 21, wherein an antireflective coating is disposed above the window layer closer to the second side of the device.

23. The method of claim 15, wherein the optoelectronic device further comprises a support layer, wherein the support layer comprises any of a diffuser layer, a dielectric layer, a semiconductor contact layer, a passivation layer, a transparent conductive oxide layer, an anti-reflective coating, a metal coating, an adhesive layer, an epoxy layer, plastic coating and a combination thereof, and the support layer is closer to the first side of the device than the p-n structure is to the first side of the device.

24. The method of claim 23, wherein the diffuser layer is disposed below the p-n structure, closer to the first side of the device than the p-n structure is to the first side of the device, wherein the diffuser is covered with a reflector layer which provides for photons to be redirected to the base layer to be absorbed and converted into electric energy.

25. The method of claim 23, wherein the dielectric layer comprises dielectric materials that are resistant to etching by acids such as hydrochloric acid, sulfuric acid or hydrofluoric acid during an epitaxial lift off (ELO) process.

26. The method of claim 23, wherein the metal coating further comprises a metallic reflector layer.
